(19) United States
(12) Patent Application Publication
(10) Pub. No.: US 2002/0151131 A1
(43) Pub. Date: Oct. 17, 2002

(54) Method of forming minute pattern and method of manufacturing semiconductor device

(75) Inventor: Kiyoshi Mori, Tokyo (JP)

Correspondence Address: McDermott, Will & Emery, 600 13th Street, N.W., Washington, DC, 20005-3096, US

(73) Assignee: Mitsubishi Denki Kabushiki Kaisha

(21) Appl. No.: 09/974,833

(22) Filed: Oct. 12, 2001

(30) Foreign Application Priority Data
Apr. 12, 2001 (JP) 2001-113902

(51) Int. Cl. H01L 21/336; H01L 21/28; H01L 21/44; H01L 21/8242

(52) U.S. Cl. 438/239; 438/299

(57) ABSTRACT

In a method of forming a minute pattern comprising a step of forming an interlayer insulating film on a substrate and a step of forming a plurality of holes in the interlayer dielectric film by means of etching, a proportion of total holes in the minute pattern is adjusted by forming dummy holes.

### BACKGROUND OF THE INVENTION

1. Field of the Invention

The present invention relates to a method of forming a minute pattern, to a semiconductor device having a minute pattern and a method of manufacturing the same. As a more specific application of the present invention, the present invention relates to a method of manufacturing a semiconductor device which suppresses occurrence of irregularities in an etch geometry, which would otherwise be caused by a difference in the proportion of openings in substrates at the time of an etching operation.

2. Background Art

FIG. 5 is a cross-sectional diagram showing a structure of a DRAM memory as one type of a semiconductor device. With reference to FIG. 5, a method of manufacturing a DRAM memory will be described by way of an example of the related art.

As shown in FIG. 5, an isolation region 2 is formed, from an insulating film, in a silicon substrate 1. A thin reliable insulating film 3 is formed on the silicon substrate 1 and the isolation region 2.

Moreover, an interconnection pattern 4 is formed on the insulating film 3. The interconnection pattern 4 comprises conductor layers consisting of a polysilicon film 4A and a tungsten silicide film 4B and insulating films 4C and 4D formed on the conductor layers. An insulating film 6 is formed on the side wall of the interconnection pattern 4 for protecting the polysilicon film 4A and the tungsten silicide film 4B, which films constitute the conductor layer.

Interlayer insulating films 13A through 13H each consisting of a nitride film or an oxide film are formed on the interconnection pattern 4, as required. During the course of formation of the interlayer insulating films 13A through 13H, processing pertaining to an exposure process, formation of holes through etching, embedding the holes with a conductor substance, and smoothing operation are iterated. By means of iteration of these operations, there are formed a metal interconnection 8, a storage node 11 serving as a lower electrode, a plate electrode 12 serving as an upper electrode, and polysilicon plugs 7 and 10 for connecting the storage node 11 to the silicon substrate 1 and a conductor plug 20 connecting the metal interconnection 8 to the polysilicon plug 7.

Thus, DRAM memory is constituted by means of iterative formation of an interconnection layer so as to spread across a plurality of layers.

By reference to FIG. 6, explanations are given of formation of the conductor plug 20 interconnecting the interconnection pattern 4 and the metal interconnection 8 and of formation of the conductor plug 20 interconnecting the polysilicon plug 7 and the metal interconnection 8.

In this case, the interconnection pattern 4, the polysilicon plug 7, and the interlayer insulating films 13A through 13C are formed on the silicon substrate 1 through repetition of an etching process and a [forming] film forming process.

Photoresist is applied to the silicon substrate 1. Subsequently, a mask pattern is transferred onto the silicon substrate 1 by means of a reduction-projection exposing operation. A resist pattern is formed on the silicon substrate 1 by means of a developing operation. The silicon substrate 1 is subjected to etching while the resist pattern is taken as a mask. Thus, a hole 20A is formed so as to reach the interconnection pattern 4 or the polysilicon plug 7. The hole 20A is embedded with an appropriate conductor, thereby completing the conductor plug 20.

Forming a hole through etching is iterated until a semiconductor device is completed.

In recent years, there has existed a demand for a higher-speed and larger-capacity semiconductor device. To this end, miniaturization of a circuit pattern of a semiconductor device has been pursued. Concurrently, in association with diversification of information processing, development of a system LSI by combination of semiconductor memory and a logic LSI has also been pursued. A system LSI formed by combination of DRAM, which is one type of semiconductor memory device, with a logic LSI is called eDRAM. The eDRAM has a characteristic of the capability of processing a large volume of image data at high speed.

In the case of such a system LSI, the range of applications of the system LSI has been widened. The proportion of a memory section, such as DRAM, and a logic LSI section in a system LSI varies in accordance with a variety of required applications. In the extreme, the majority of one chip is occupied by memory. Alternatively, the majority of one chip is occupied by a logic LSI. Thus, the proportion of DRAM and a logic LSI varies in accordance with the application of the system LSI. Even when substrates of different types are identical in terms of the size of a chip produced by a single shot of exposure, the entire pattern of a required chip varies from one application to another. In many cases, the proportion of holes varies.

When holes are formed through etching under fixed conditions, a difference in the proportion of holes between substrates causes variations in the geometry of the thus-formed holes and affects a margin in a manufacturing process.

The influence on the geometry of an etched hole and a margin in a manufacturing process poses a serious problem.

In order to avoid variations in the geometry of an etched hole, varying etching conditions are adapted in accordance with the type of a substrate, and poses a problem of a progressive drop in processing speed in association with an increase in the variety of substrates.

### SUMMARY OF THE INVENTION

Accordingly, the object of the present invention is to provide a method for solving the problem set forth, as well as to provide a method for etching substrates having a different proportion of holes under fixed conditions while variations in the geometry of holes and a drop in a margin in a manufacturing process are suppressed.

In the present application, the expression “proportion of holes” is considered on a per-wafer basis. In short, proportion of holes means a total area of holes with respect to the area of a wafer. An etching operation for forming holes is usually performed on a per-wafer basis.

However, a plurality of chips are formed in a single wafer. An identical pattern is transferred to the chips, by means of shooting. Accordingly, the proportion of holes for a wafer is usually substituted by the proportion of holes per chip.

Here, the expression “fixing a proportion of holes or maintaining the proportion of holes within a given range” means that, when wafers of different patterns are processed successively in a single processing apparatus, the wafers are compared with each other, and the proportion of holes is kept fixed or within a given range.

According to one aspect of the present invention, in a method of forming a minute pattern, an interlayer insulating film is formed on a substrate. A plurality of holes are formed in the interlayer insulating film by means of etching, and a proportion of the holes in the substrate is adjusted.

In another aspect of the present invention, in the method of forming a minute pattern, the proportion of the holes is adjusted by means of causing a plurality of holes to include dummy holes that do not constitute a required pattern.

In another aspect of the present invention, in the method of forming a minute pattern, the dummy holes are included such that the proportion of the holes is maintained within a certain range among a plurality of substrates.

In another aspect of the present invention, in the method of forming a minute pattern, the dummy holes suppress variations in the proportion of the holes within a range of 50% among a plurality of substrates.

In another aspect of the present invention, in a method of manufacturing a semiconductor device, an interconnection pattern is formed on the surface of a substrate. An interlayer insulating film is formed on the interconnection pattern. Holes are formed in the interconnection pattern so as to penetrate through the interlayer insulating film and to reach the interconnection pattern by means of etching. A proportion of the holes in the substrate is adjusted.

In another aspect of the present invention, in the method of manufacturing a semiconductor device, the proportion of the holes is adjusted by means of causing the plurality of holes to include dummy holes which do not constitute a required pattern.

In another aspect of the present invention, in the method of manufacturing a semiconductor device, the dummy holes are included such that the proportion of the holes is maintained within a certain range among a plurality of substrates.

In another aspect of the present invention, in the method of manufacturing a semiconductor device, the dummy holes suppress variations in the proportion of the holes within a range of 50% among a plurality of substrates.

In another aspect of the present invention, in the method of manufacturing a semiconductor device, the dummy holes are positioned on an area or areas of the substrate, where no problem will arise in the real circuit.

In another aspect of the present invention, in the method of manufacturing a semiconductor device, a dummy pattern is provided and a dummy hole or holes are formed on the dummy pattern.

In another aspect of the present invention, in the method of manufacturing a semiconductor device, a dummy pattern which is not required for forming a real interconnection pattern is provided, and the dummy holes are formed on the dummy pattern.

In another aspect of the present invention, in the method of manufacturing a semiconductor device, the dummy holes are arranged such that holes required for constituting a real circuit pattern do not assume a specific pattern which is apt to cause defects in a real circuit.

Other and further objects, features and advantages of the invention will appear more fully from the following description.

### BRIEF DESCRIPTION OF THE DRAWINGS

FIG. 1 is a cross-sectional view showing a semiconductor device manufactured in accordance with a first embodiment of the present invention.

FIGS. 2A through 2C are schematic diagrams showing a case where substrates or wafers having different proportions of holes are experimentally subjected to etching.

FIG. 3 is a cross-sectional view for describing processes of manufacturing a semiconductor device according to a second embodiment of the present invention.

4A and 4B are schematic top views for describing processes for manufacturing a semiconductor device according to a third embodiment of the present invention.

FIG. 5 is a cross-sectional diagram showing a structure of a DRAM memory as one type of a semiconductor device.

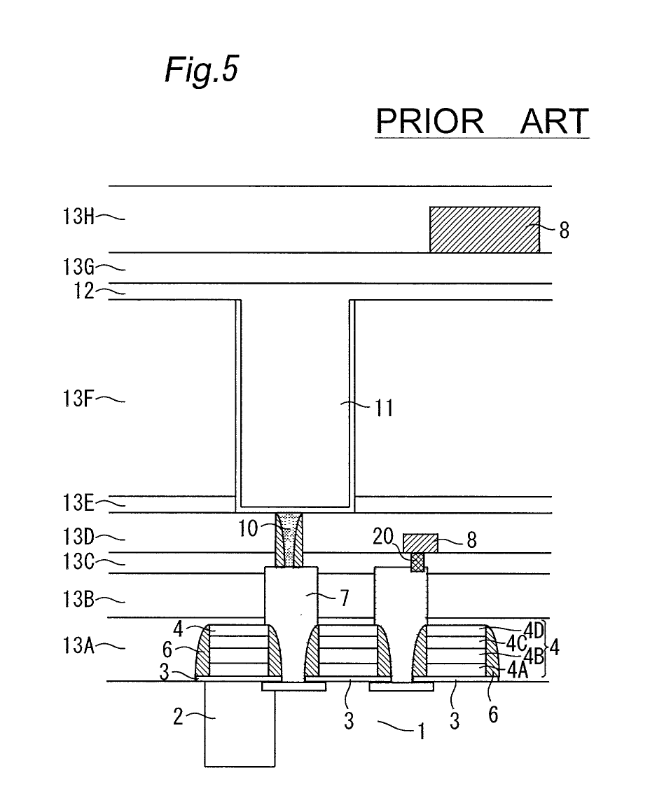

FIG. 6 is across-sectional diagram for describing formation of the conductor plug interconnecting the interconnection pattern and the metal interconnection and of formation of the conductor plug interconnecting the polysilicon plug and the metal interconnection.

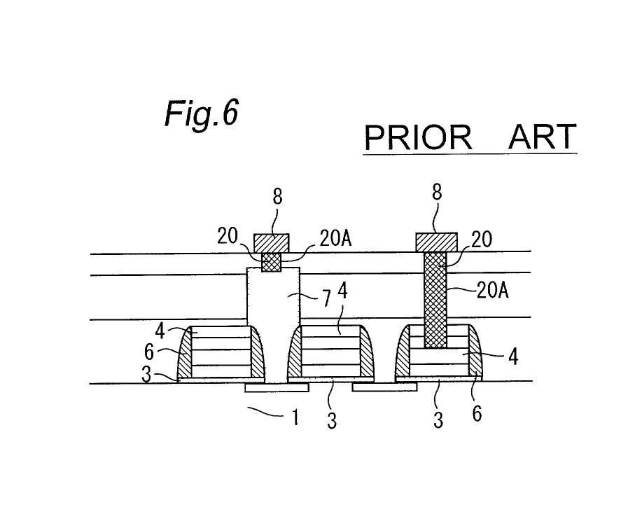

### DETAILED DESCRIPTION OF THE PREFERRED EMBODIMENTS

Embodiments of the present invention will be described by reference to the accompanying drawings. Throughout the drawings, like parts or corresponding parts are assigned the same reference numerals, and repeated explanations thereof are simplified or omitted.

First Embodiment

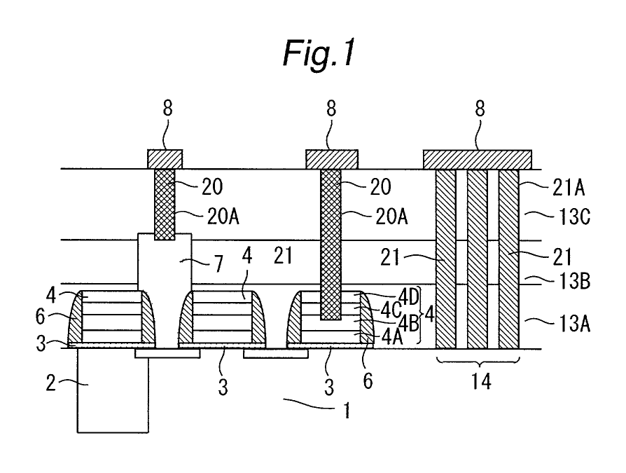

FIG. 1 is a cross-sectional view showing a semiconductor device manufactured in accordance with a first embodiment of the present invention.

As shown in FIG. 1, reference numeral 1 designates a semiconductor substrate; 2 designates an isolation region formed from a insulating film; and 3 designates a thin reliable insulating film. On the insulating film 3 are formed, in the sequence given, a conductive polysilicon film 4A, a conductive tungsten silicide film 4B, and insulating films 4C and 4D each formed from an oxide or nitride film. An interconnection pattern 4 is formed from the polysilicon film 4A, the tungsten silicide film 4B, and the insulating films 4C and 4D.

Reference numerals 13A through 13C designate interlayer insulating films each formed from an oxide or nitride film. In addition to the interconnection pattern 4, a polysilicon plug 7, for example, is formed in the interlayer insulating films 13A through 13C. The interlayer insulating films 13A through 13C play a role of insulating the thus-layered metal interconnections.

Reference numeral 8 designates a metal interconnection formed on the interlayer insulating film 13C. Reference numeral 20A designates a hole formed in the interlayer insulating films 13A through 13C, and 20 designates a conductor plug formed by embedding the hole 20A with a conductive substance.

One of the metal interconnections 8 is connected, by way of a conductor plug 20, to one interconnection pattern 4 formed in the interlayer insulating film 13A. Another of the metal interconnections 8 is connected, by way of the conductor plug 20, to the polysilicon plug 7 formed in the interlayer insulating film 13B and 13A.

Reference numeral 21A designates dummy holes formed in the interlayer insulating films 13A through 13C, and 21 designates dummy plugs formed by means of embedding the dummy holes 2 1A with a conductive substance. The metal interconnection 8 is formed on the tops of the dummy plugs 21, and lower portions of the dummy plugs 21 reach an area 14 of the substrate 1, where no problem is posed in the circuit of the substrate 1.

The number of dummy holes 21A is determined in consideration of the proportion of the holes 20A in which the conductor plugs 20 are to be formed, such that the proportion of the total holes 20A and 21A is adjusted. Accordingly, the proportion of the total holes can be adjusted so as to become substantially fixed in connection with a variety of types of substrates having different proportions of DRAMs and logic LSIs for example.

Next will be described processes of forming the hole 20A and the dummy hole 21A in the interlayer insulating films 13A through 13C, which reach the interconnection pattern 4 or the polysilicon plug 7, while the proportion of holes is adjusted.

Photoresist is applied to the top layer 13C of the interlayer insulating films 13A through 13C in which the interconnection pattern 4 and the polysilicon plug 7 are formed, thereby forming a thin resist film. Next, the substrate 1 is subjected to reduced-projection exposure and development, whereby a mask pattern is transferred onto the resist thin film. As a result, a resist pattern is formed on the interlayer dielectric film 13C. At this time, in order to unify a proportion of holes among substrates of different types, the mask pattern also includes pattern images of dummy holes which are irrelevant in terms of a real circuit. As a result, a substantially fixed proportion of holes is achieved among substrates of different types. Hence, the resist pattern formed on the interlayer insulating film 13C is also adjusted such that a substantially fixed proportion of holes is achieved.

The substrate is subjected to etching while the resist pattern is taken as a mask. By means of the etching operation, there are formed, as required, the hole 20A penetrating through the interlayer insulating films 13A through 13C to the interconnection pattern 4, the hole 20A penetrating through the interlayer insulating film 13C to the polysilicon plug 7, or the dummy holes 21A penetrating through the interlayer insulating films 13A through 13C to the area 14 of the substrate 1, where no problem will arise in the real circuits of the substrate 1.

The holes 20A are embedded with conductive substances, thereby forming the conductor plugs 20. The dummy holes 21A are embedded with a conductive substance, thereby forming the dummy plugs 21. The metal interconnections 8 are formed on the conductor plugs 20 or the dummy plugs 21, as required.

In the manner as mentioned above, the proportion of holes is adjusted, thereby forming a minute pattern.

The first embodiment has been described by reference to an example method. Specifically, a resist pattern is formed by means of projection exposure, in which a photomask pattern is transferred by means of application of a resist film, and the substrate is subjected to etching. However, the present invention is not limited to such a method. For instance, within the scope of the invention, there may be employed another method, in which a resist pattern is formed by means of the exposure technique using an electron beam, and the substrate is subjected to etching while the resist pattern is used as a mask.

The dummy holes 21A are embedded with the same conductive substance as that used for filling the holes 20A, in order to perform processing smoothly. However, the present invention is not limited to a conductive substance. The dummy holes may be embedded with an insulation substance or another substance falling within the scope of the invention.

In the first embodiment, the proportion of holes is adjusted such that substrates achieve a substantially fixed proportion of holes. However, the present invention is not limited to such an embodiment. In order to confine to an allowable value or less the variation in the geometry of holes due to a difference in proportion of holes between substrates, variation in proportion of holes between substrates is preferably reduced to a range of about 50%.

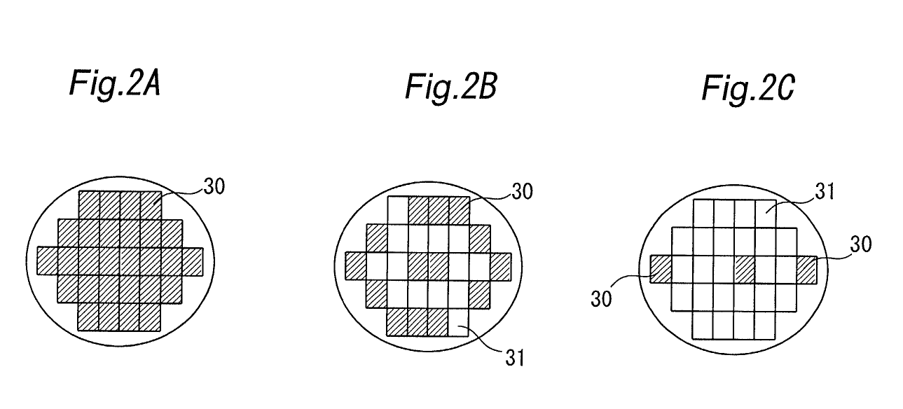

According to the method, when holes are formed in substrates of different types through use of different patterns by means of a single processing apparatus, a fixed range in proportion of holes can be achieved among substrates of different types, through use of dummy holes. Accordingly, even when holes are formed under fixed processing conditions, variations in the geometry of holes, which would arise during formation of holes, can be suppressed. Reduction in variations in the geometry of holes will be described by reference to FIGS. 2A through 2C.

As shown in FIGS. 2A through 2C, reference numeral 30 designates a chip to be subjected to exposure; and 31 designates a chip which is not to be subjected to exposure. FIG. 2A shows a substrate in which all chips have been exposed. FIG. 2B shows a substrate in which one-half of the chips have been exposed. FIG. 2C shows a substrate in which only 10% of all chips have been exposed. Here, chips 30 which are to be exposed and chips 31 which are not to be exposed are provided on a single substrate, through use of the same mask pattern, thereby changing the proportion of holes.

After formation of samples, the samples are subjected to etching, and the geometry of samples are checked. As a result, it is found that a difference in the proportion of holes induces a difference in the sizes of holes and that the holes differ from each other in shape.

In a case where substrates having different proportions of holes are to be etched, etching conditions must be changed in accordance with the respective proportions of holes. In contrast, in the first embodiment, a fixed range in the proportion of the holes is achieved is achieved among the substrates, through use of the dummy holes 21A. Accordingly, even when holes are formed in substrates of different types through use of a single processing apparatus, holes can be formed smoothly under the same conditions while uniformity of geometry of holes is ensured without changing etching conditions for each of the substrates.

The present invention has been described by means of taking, as an example, formation of holes for interconnecting the metal interconnection 8, and the lower interconnection pattern 4 or the polysilicon plug 7. However, the present invention is not limited to such an embodiment. The present invention may be employed in another etching operation falling within the scope of the invention.

Second Embodiment

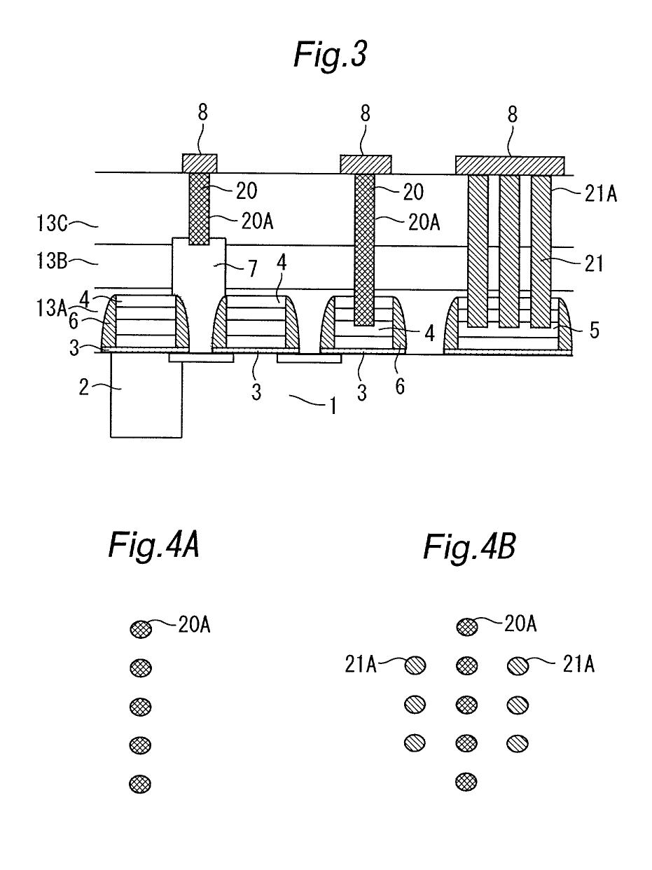

FIG. 3 is a cross-sectional view for describing processes of manufacturing a semiconductor device according to a second embodiment of the present invention.

As shown in FIG. 3, reference numeral 5 designates a lower dummy pattern that is not used as a part of a real circuit. A dummy pattern 5 is provided at the time of formation of the interconnection pattern 4, for reasons of preventing occurrence of a so-called dishing phenomenon, which would otherwise be caused when a smoothing process involving CMP is employed. Accordingly, the dummy pattern 5 does not function as a real circuit.

As shown in FIG. 3, in the second embodiment, the dummy holes 21A are formed so as to extend to the dummy pattern 5. However, the dummy pattern 5 does not function as a real circuit, as mentioned above. Hence, even when the dummy plugs 21 are formed on the dummy pattern 5, no influence is imposed on a real circuit.

In other respects, the processes are the same as those described in connection with the first embodiment, and hence repeated explanations thereof are omitted.

As mentioned above, in the second embodiment, the dummy holes 21A are provided without imposing any influence on a real circuit, thereby maintaining a fixed range in proportion of holes in substrates of different types. Even when holes are formed in substrates of different types through use of different patterns in a single processing apparatus, holes can be formed smoothly under the same conditions while the uniformity of geometry of holes and reliability of a real circuit are ensured, without a necessity of adjusting etching conditions for each of the substrates.

In the second embodiment, the dummy holes 21 are adjusted to be formed on the dummy pattern 5, which pattern is formed at the time of formation of an interconnection pattern 4. However, the present invention is not limited to the second embodiment. Other dummy patterns may be formed for forming the dummy holes 21A at the time of formation of the interconnection pattern 4 or the other time.

Third Embodiment

FIGS. 4A and 4B are schematic top views for describing processes for manufacturing a semiconductor device according to a third embodiment of the present invention. FIG. 4A shows the layout of holes at the time of formation of a specific pattern which would cause defects in a circuit. FIG. 4B shows the layout of holes when no specific pattern is formed. As shown in FIGS. 4A and 4B, reference numeral 20A designates holes for forming a conductor plug, and 21A designates dummy holes.

As shown in FIG. 4A, the holes 20A are aligned in line, thereby forming a specific pattern. Such a specific pattern is known to be apt to cause defects in a circuit.

In the third embodiment, as shown in FIG. 4B, the dummy holes 21A for adjusting the proportion of holes are arranged around the holes 20A required for a real circuit.

Thus, in a case where the layout of holes 20A required for a real circuit may constitute a specific pattern, the layout can be modified, thereby preventing occurrence of defects in a circuit.

Conversely, dummy holes can be selectively arranged such that the layout of the dummy holes 21A does not assume a specific pattern that is apt to cause defects in a circuit.

In other respects, the processes are the same as those described in connection with the first and second embodiments, and hence repeated explanations thereof are omitted.

In the third embodiment, the holes 20A required for a real circuit can be prevented from assuming a specific circuit pattern, which would be apt to cause circuit defects, by means of effectively arranging the dummy holes 21A while the proportion of holes is adjusted.

The features and the advantages of the present invention as described above may be summarized as follows.

According to one aspect of the present invention, in a method of forming a minute pattern and manufacturing a semiconductor device, the proportions of holes formed in substrates of different types can be adjusted so as to fall within a certain range, through use of dummy holes. Accordingly, even when holes are formed in different patterns in respective substrates of different types by means of a single processing apparatus, holes can be formed smoothly under fixed etching conditions while the uniformity of geometry of holes and the reliability of a real circuit are ensured, without a necessity of changing etching conditions for each of the substrates.

In another aspect of, in a method of forming a minute pattern and manufacturing a semiconductor device, a fixed range in proportion of holes can be ensured among substrates of different types. Accordingly, processing of the respective substrates does not involve a necessity of changing etching conditions in accordance with patterns of respective types, formation of holes can be performed successively through use of a single processing apparatus under fixed etching conditions, and hence processing can be pursued smoothly.

In another aspect of, in a method of forming a minute pattern and manufacturing a semiconductor device, dummy holes are formed so as to prevent holes from assuming a specific pattern required for a real circuit. Accordingly, the geometry of holes formed in the present invention can be made more stable than that of holes formed without involvement of formation of dummy holes.

Obviously many modifications and variations of the present invention are possible in the light of the above teachings. It is therefore to be understood that within the scope of the appended claims the invention may by practiced otherwise than as specifically described.

The entire disclosure of a Japanese Patent Application No. 2001-113902, filed on Apr. 12, 2001 including specification, claims, drawings and summary, on which the Convention priority of the present application is based, are incorporated herein by reference in its entirety.

1. A method of forming a minute pattern, said method comprising the steps of;
forming an interlayer insulating film on a substrate; and
forming a plurality of holes in the interlayer insulating film by means of etching;
wherein a proportion of the holes in the substrate is adjusted.

2. The method of forming a minute pattern according to claim 1, wherein the proportion of the holes is adjusted by means of causing the plurality of holes to include dummy holes that do not constitute a required pattern.

3. The method of forming a minute pattern according to claim 2, wherein the dummy holes are included such that the proportion of the holes is maintained within a certain range among a plurality of substrates.

4. The method of forming a minute pattern according to claim 2, wherein the dummy holes suppress variations in the proportion of the holes within a range of 50% among a plurality of substrates.

5. A method of manufacturing a semiconductor device, said method comprising the steps of;
forming an interconnection pattern on the surface of a substrate;
forming an interlayer insulating film on the interconnection pattern; and
forming holes so as to penetrate through the interlayer insulating film and to reach the interconnection pattern by means of etching;
wherein a proportion of the holes in the substrate is adjusted.

6. The method of manufacturing a semiconductor device according to claim 5, wherein the proportion of the holes is adjusted by means of causing the plurality of holes to include dummy holes which do not constitute a required pattern.

7. The method of manufacturing a semiconductor device according to claim 6, wherein the dummy holes are positioned on an area or areas of the substrate, where no problem will arise in the real circuit.

8. The method of manufacturing a semiconductor device according to claim 7, wherein, in the step of forming the interconnection pattern, a dummy pattern is provided, and, in the step of forming the holes, a dummy hole or holes are formed on the dummy pattern.

9. The method of manufacturing a semiconductor device according to claim 7, wherein, in the step of forming the interconnection pattern, a dummy pattern which is not required for forming a real interconnection pattern is provided, and, in the step of forming the holes, the dummy holes are formed on the dummy pattern.

10. The method of manufacturing a semiconductor device according to claim 7 , wherein the dummy holes are arranged such that holes required for constituting a real circuit pattern do not assume a specific pattern which is apt to cause defects in a real circuit.

11. The method of manufacturing a semiconductor device according to claim 6, wherein the dummy holes are included such that the proportion of holes is maintained within a certain range among a plurality of substrates.

12. The method of manufacturing a semiconductor device according to claim 11, wherein the dummy holes are positioned on an area or areas of the substrate, where no problem will arise in the real circuit.

13. The method of manufacturing a semiconductor device according to claim 12, wherein, in the step of forming the interconnection pattern, a dummy pattern is provided, and, in the step of forming the holes, a dummy hole or holes are formed on the dummy pattern.

14. The method of manufacturing a semiconductor device according to claim 12, wherein, in the step of forming the interconnection pattern, a dummy pattern which is not required for forming a real interconnection pattern is provided and, in the step of forming the holes, the dummy holes are formed on the dummy pattern.

15. The method of manufacturing a semiconductor device according to claim 12, wherein the dummy holes are arranged such that holes required for constituting a real circuit pattern do not assume a specific pattern which is apt to cause defects in a real circuit.

16. The method of manufacturing a semiconductor device according to claim 6, wherein the dummy holes suppress variations in the proportion of the holes within a range of 50% among a plurality of substrates.

17. The method of manufacturing a semiconductor device according to claim 16, wherein the dummy holes are positioned on an area or areas of the substrate, where no problem will arise in the real circuit.

18. The method of manufacturing a semiconductor device according to claim 17, wherein, in the step of forming the interconnection pattern, a dummy pattern is provided, and, in the step of forming the holes, a dummy hole or holes are formed on the dummy pattern.

19. The method of manufacturing a semiconductor device according to claim 17, wherein, in the step of forming the interconnection pattern, a dummy pattern which is not required for forming a real interconnection pattern is provided, and, in the step of forming the holes, the dummy holes are formed on the dummy pattern.

20. The method of manufacturing a semiconductor device according to claim 17, wherein the dummy holes are arranged such that holes required for constituting a real circuit pattern do not assume a specific pattern which is apt to cause defects in a real circuit.
